(19) United States
(12) Patent Application Publication
(10) Pub. No.: US 2014/0060649 A1
(43) Pub. Date: Mar. 6, 2014

(54) DEVICE, PANEL HOLDER, AND SYSTEM FOR GENERATING ELECTRIC POWER FROM SOLAR RADIATION

(71) Applicant: Petrus Paulus Carolus Maria Stassen, Waalwijk (NL)

(72) Inventor: Petrus Paulus Carolus Maria Stassen, Waalwijk (NL)

(73) Assignee: TULIPPS SOLAR INTERNATIONAL B.V., Eindhoven (NL)

(21) Appl. No.: 14/114,638

(22) PCT Filed: Apr. 27, 2012
(86) PCT No.: PCT/NL2012/050294

§ 371 Date: Oct. 29, 2013

(30) Foreign Application Priority Data
Apr. 29, 2011 (NL) 2006685

(51) Int. Cl. H01L 31/042

(52) U.S. Cl. CPC H01L 31/0424
USPC 136/259

(57) ABSTRACT

A device (1) for generating electric power from solar radiation comprises a solar panel (2) and a panel holder (3). The panel holder comprsies two panel holder parts (4A, 4B) on opposite sides. Elongate profiles (5) are coupled to the panel holder parts. This device has different bending resistances in the directions parallel and perpendicular to the profiles. Since bending of the solar panel can thus be permitted in a controlled manner, it is possible to use a thin glass plate for the panel.

The present invention relates to a device for generating electric power from solar radiation, comprising a solar panel provided with at least one photovoltaic cell and a panel holder for holding the solar panel.

The invention also relates to a panel holder and a system for generating electric power from solar radiation.

Such a device is used to generate electric power in the form of electricity from solar radiation by means of one or a greater number of photovoltaic cells. The photovoltaic cells are here used in a solar panel which comprises, on a sunlight side, a shield for the protection of the cells. In order as far as possible to let the incident sunlight pass freely through to the cells, a glass plate, practically without exception, is used as the shield, owing to the particularly translucent property of glass. At the same time, a glass plate is strong and durable. The photovoltaic cells are laminated with the glass plate. However, such devices are relatively heavy and need to be installed with a number of auxiliary devices, such as, for example, an aluminium supporting structure.

Because the solar panel with the glass plate is relatively fragile, the solar panel is in known devices held by a panel holder. The panel holder lends strength to the solar panel and protects it against external mechanical load. In the known devices, the panel holder is normally formed by a frame which encloses the solar panel around a circumferential edge. Apart from protecting the solar panel, the panel holder enables the solar panel to be installed on a foundation, such as, for example, a roof of a building. The frame, which in practice is normally made of aluminium, can in this case be placed on one or a number of support bodies, such as support feet. Although devices of this kind for generating electricity from sunlight, known as solar cell modules, have been used for many years in all sorts of variants, the technology remains in search of marked improvements in terms of efficiency, weight reduction and, above all, also reduction in the cost of the devices.

Large solar panels, that is to say solar panels having a relatively large surface area, which can hence comprise more photovoltaic cells, have the important advantage that the costs per unit of area for the generation of electric power are lower compared with a plurality of smaller solar panels which together have the same surface area and quantity of photovoltaic cells.

The installation of a small number of large solar panels is simpler and more cost-effective than the installation of a greater number of small solar panels for obtaining the same effective surface area.

This therefore makes it desirable to use relatively large solar panels in a device for generating electric power from solar radiation. However, the size of the usable solar panels is, for practical reasons, limited.

The drawback with large solar panels is namely that, for sufficient strength, particularly of the relatively fragile glass plate, more and/or heavier materials are normally required. Thus, in the case of the current relatively large solar panels, for example, a thick glass plate is used in the solar panel in order to be able to withstand the maximum loads thereon, prescribed in the standards, without breakage or some other kind of damage, or significant reduction in photovoltaic electricity production. A thick glass plate here has the advantage that it is relatively firm and rigid. Bending of the glass plate is generally undesirable, since this can lead to damage to the solar cells fitted on the glass plate, i.e. photovoltaic cells, or the soldered or glued cell joints.

However, the thick glass plate forms a relatively heavy weight which must be borne by the panel holder and support bodies, for example support feet, which must consequently also be made stronger. This normally produces a further increase in weight of the device. The panel holder should here ensure that the solar panel does not start bending as a result of a load applied to the solar panel.

The result of all this is that the solar panel and the panel holder have a large relative weight in relation to the effective surface area of the solar panel. During installation, the solar panels must normally be lifted manually into the installation position. As a result of a thereto related maximally practically desirable weight, the maximum size of the solar panels which can be used is hereby limited.

As a result of the large relative weight per surface area, furthermore, the device is relatively expensive and cannot be used on all foundations, such as, for example, weaker lightweight roofs.

The object of the present invention is to provide an improved device for generating electric power from solar radiation. More particularly, the object of the present invention is to provide a device for generating electric power from solar radiation, which device has a favourable relative weight in relation to the effective surface area of the solar panel.

A first aspect of the invention provides a device according to claim 1.

By allowing a solar panel to be bent in a controlled manner, the device being preferably supported on or close to the corners, it is possible to permit a specific deflection of the solar panel without substantial damage to the, for example, laminated photovoltaic cell or photovoltaic cells connected to the glass plate.

The thin glass plate should be bendable such that the glass plate and the underlying photovoltaic cells or photovoltaic thin film can follow, without breaking, a bending of the solar panel as a consequence of a load arising during normal use of solar panels. A load arising during normal use of solar panels comprises, for example, an exerted pressure and suction force of 2400 Pa and/or 5400 Pa in accordance with the applicable standards IEC 61215:2005 and IEC 61646:2008.

When the solar panel is subjected to a load, the panel holder can bend along with the solar panel.

In the device according to the first aspect of the invention, the controlled bending of the device is obtained by making the relative deflection in the first direction substantially smaller than in the second direction. As a result, the bending of the device occurs particularly about a bending axis in the first direction. The photovoltaic cell or photovoltaic cells which have been fitted on the bendable glass plate are less damaged by a bending which occurs particularly about one bending axis than by an equal bending about a plurality of bending axes.

A deflection of the solar panel in the second direction here has the advantage that the bending resistance of the solar panel in the first direction is hereby increased as a result of the material stresses which are generated in the solar panel by the bending in the second direction. This increase in rigidity in the solar panel in the first direction is particularly of advantage in relatively large solar panels having a largest dimension in the first direction, whereby specifically the longer, and hence normally weaker, length direction is strengthened. This solar panel can hereby withstand a higher load, or can be made in thinner and thus lighter construction for the resistance of a prescribed maximally permitted load.

It can here be advantageous to make the first direction, in which the relative deflection is lowest, substantially coincide with the direction in which the photovoltaic cell or photovoltaic cells, or connections to or between the photovoltaic cell or cells, are most susceptible to deflection. In a layer comprising a photovoltaic cell or photovoltaic cells, there is generally a direction in which the layer is most susceptible to damage to the photovoltaic cell or cells, for example a breakage of the soldered or glued cell joints. By making this direction coincide with the first direction, the chance of damage to the layer comprising a photovoltaic cell or photovoltaic cells is diminished.

The relative deflection of the solar panel is the ratio between the amount of deflection which occurs per length of the solar panel in a specific direction.

In one embodiment, the relative deflection in the second direction is, for example, at least one and a half times the relative deflection in the first direction, preferably at least twice the relative deflection in the first direction.

As a result of the insight that, when a solar panel is subjected to a load, a specific bending of the solar panel can be permitted in a controlled manner, it is possible to use a thin glass plate even in relatively large solar panels. A device of this type can satisfy the strength required for such devices, as described in standards IEC 61215 and IEC 61646. Thus the panel holder, for example, in respect of a glass plate having a length dimension of, for example, 200 cm or longer, and a width dimension of 164 cm and 2 mm thickness, provides a sufficiently strong device which is capable of withstanding a pressure exerted on the glass plate and a suction force of 2400 Pa and/or 5400 Pa, in accordance with standards IEC 61215:2005 and IEC 61646:2008. By virtue of the fact that the device can adopt a relatively thin glass plate without the need for a relatively heavy, rigid panel holder in return, a relative weight of the device per effective surface area can remain considerably lower compared with devices in which thick glass panels and/or heavy panel holders are used, wherein no or very little bending of the glass plate is permitted.

Moreover, the use of bendable glass plates where bending is permitted during load makes it possible to withstand large peak loads exerted on the solar panel. Thus, in one embodiment of the invention, it was found that, in the conductance of a so-called Module Breakage Test, directed at the splinter behaviour of glass upon breakage, the thin glass plate, as a result of the permitted bending, is capable of absorbing a peak load without breaking. Thicker glass plates which are accommodated rigidly in a frame would just break under such a load.

A Module Breakage Test is a destructive safety test which simulates a situation in which a workman falls on the module during installation, the test being designed to destroy the module in order to see how the glass plate splinters.

The device according to the invention offers a wide range of use and makes it possible to realize a lightweight large solar panel, for example provided with 120×15.2 cm (6″) cells, and having dimensions of, for example, 200 cm by 164 cm. The low specific weight of this 120-cell module can result in a very low roof load of less than 10 kg/m2, whereby this system offers a solution for relatively weak roofs, such as, for example, light industrial roofs. In some embodiments, the effective surface area of a solar panel can be increased by more than 50%, compared with a conventional device, whilst the weight remains the same. Apart from a lowering of a relative weight per effective surface area of the device, a relatively thin glass plate also yields a cost advantage. For the relatively thin solar panel and the less rigid panel holder, less material is necessary. Moreover, light transmission of a glass plate is dependent on the thickness thereof. Thus, the light transmission of a glass plate of 2 mm thickness is significantly higher than a light transmission of conventional glass panels of at least 4 mm thickness. A higher light transmission of a glass plate leads to a higher Watt-peak (Wp) energy output of the solar panel with given cells and thus a better financial return of the device.

In one embodiment, the edge of the solar panel is free from a rigid frame which encloses the complete circumferential edge of the solar panel. In known solar cell modules, the complete edge of the solar panel is encloseed with a rigid frame, as described in the introduction. The function of this rigid frame is to hold the solar panel in a rigid structure so as to prevent bending of the solar panel. Because in the present device bending of the solar panel should specifically be allowed, a rigid frame of this type is undesirable since it prevents the solar panel from bending. The use of a rigid frame in combination with a thin bendable glass plate will normally, during a load, lead to breakage of the glass plate and/or unacceptable damage to the photovoltaic cells or connections to or between the photovoltaic cells of the solar panel.

Preferably, in the device, the complete circumferential edge of the solar panel is free from a rigid frame which encloses the edge of the solar panel.

A further advantage of a free circumferential edge is that the shaping of the solar panel is less restricted. The shape of the solar panel can thus be adapted to the location in which the device is placed. It is also possible to round off the corners of the solar panel. This reduces the chance of the glass plate being broken if the corner of the solar panel is banged against an object. Moreover, the chance of injury to an installer from the corner points of the solar panel can herewith be considerably reduced.

The solar panel is preferably fastened on a top side of the panel holder. In one embodiment, the length and width dimensions of the solar panel are greater than the length and width dimensions of the panel holder on which the solar panel is fastened. As a result, a panel holder can fall entirely beneath the solar panel and this is better protected against negative effects from external influences, such as precipitation and UV radiation.

In one embodiment, the panel holder comprises four support bodies, which are fitted on or close to the corner points of the panel holder in order to support the panel holder and the panel held thereon. The support of the panel holder on or close to the corner points with support bodies enables the panel to bend between the support bodies. The support bodies can be, for example, openings for the reception of supporting elements or support feet therein. The support bodies can also themselves form supporting elements or support feet. By making the bending take place fully within corner points, the bending of the solar panel can be well controlled, wherein, with a load distributed substantially evenly over the surface of the solar panel, the bending of the solar panel takes place particularly about one bending axis.

As an alternative, or in addition thereto, support bodies can be provided on one side of the device, these support bodies preferably being provided on that side of the device which runs parallel to the first direction.

It can be advantageous to position with some flexibility at least two support bodies placed on one side of the device, by not fixedly connecting these, for example, to a foundation. As a result of this flexibility, the support bodies of the device will not be able to prevent deflection of the panel holder and of the solar panel held thereon.

In one embodiment, the first bending resistance is at least twice as great as the second bending resistance, preferably four times greater than the second bending resistance. By making the bending resistance in the first direction greater than in the second direction, it is possible to obtain a first relative deflection of the solar panel in the first direction which is substantially smaller than the second relative deflection of the solar panel in the second direction.

In one embodiment, the device has a length direction and a width direction, the first direction being the length direction of the device and the second direction being the width direction of the device.

By constructing the device such that a bending resistance thereof in the width direction is lower than a bending resistance in the length direction, the device will bend, in the event of a uniform load upon the solar panel, substantially about a bending axis in the length direction. This generates space for the solar panel to be able to deflect uniformly in the width direction, with much less deflection in the length direction. By making most of the deflection take place in the width direction, with a uniform relationship between the first relative deflection in the first direction and the second relative deflection in the second direction, the lowest total deflection of the solar panel is obtained.

In one embodiment, the panel holder comprises on the first side a first panel holder part, which extends in the second direction beneath the solar panel and is provided with a first and a second support body, and comprises on the second side a second panel holder part, which extends in the second direction beneath the solar panel and is provided with a third and a fourth support body, which panel holder parts, on a top side, at least partially receive the solar panel and allow a deflection in the second direction when a load is evenly distributed over the surface of the solar panel.

The panel holder parts serve as a base for possible integration of desired functions, such as, for example, a support base for the positioning of the device, a coupling base for a coupling of two or more devices, a base for fastening means for the fastening of the support bodies, integration of electrical components, temperature control means, etc.

Moreover, the panel holder parts can be well constructed with a lower bending resistance than the bending resistance of the panel holder in the first direction in order to allow a deflection thereof in the second direction, for example by a suitable choice of material for the panel holder parts, whether or not in combination with a certain dimension, shape and thickness thereof. The panel holder parts are made, for example, of a plastic.

In one embodiment, the panel holder comprises at least one profile which extends in the first direction beneath the solar panel, wherein at least one profile on both sides is coupled to the two panel holder parts and extends therebetween.

A combination of two panel holder parts on two mutually opposing sides of a solar panel, with one or more profiles therebetween, is a particularly suitable construction for the supporting of solar panels with a thin glass plate. The construction makes it possible to make efficient and relatively light devices and systems for generating electric power from solar radiation.

A second aspect of the invention provides a device of this type, as described in claim 8.

Such a construction can be realized such that it, on the one hand, can withstand a local peak load by permitting bending of the thin glass plate, while, on the other hand, if a load is distributed substantially evenly over the surface of the solar panel up to a maximally permitted load, photovoltaic cells connected to the glass plate can not or not much be damaged.

In one embodiment, the panel holder comprises two or more elongate profiles, which extend in parallel in the first direction. Through the use of a plurality of profiles extending in the first direction, the two panel holders situated on opposite sides can be connected to each other, the two or more profiles substantially contributing to the first bending resistance in the first direction. A stable and strong construction is hereby obtained.

By making the panel holder parts of plastic, for example, and the two or more profiles of a metal, for example aluminium, a hybrid construction which serves as a panel holder is efficiently formed. The panel holder parts can be used to integrate various functions in the panel holder, such as the forming of support bodies for supporting the panel holder and cavities for receiving the ends of the profiles. Plastic is a material which lends itself well to the integration of such functions. The one or more profiles can be easily produced from metal. The one or more profiles should give a relatively large resistance in the first direction and be able to support the solar panel.

In one embodiment, the solar panel is bonded onto one or more profiles. This bonding can be achieved with a suitable bonding agent, such as a cement or glue. The bonding agent preferably has a large tensile strength characteristic of, for example, 3 Mpa and a large elongation of, for example, about 250% according to ISO 37. The bonding agent preferably has a less than 2% volume change and is not significantly affected by exposure to UV radiation. Preferably, the solar panel is also bonded onto each of the panel holder parts.

In one embodiment, the one or more profiles project with each of the ends thereof into a receiving cavity provided in the panel holder parts provided on both sides and the one or more profiles is/are freely movable therein with the ends. Such a construction offers a good coupling between the panel holder parts and the one or more profiles.

In one embodiment, each of the one or more profiles comprises a hollow or non-hollow bar shaped body made from one piece of a material chosen from a metal or a plastic, for example steel or aluminium, or, as an alternative, a composite such as a glass fibre reinforced plastic or glass filament reinforced plastic. By producing the profiles from one piece of a material, the one or more profiles are easily and efficiently obtained.

In an alternative embodiment, the one or more profiles can be built up in length and/or width from various materials and/or various bodies. A profile does not need to have a constant cross section over the length thereof.

In one embodiment, at least one of the one or more profiles has, in a length direction, a continuous cavity, through which a heat-carrying medium can be passed. The efficiency of the photovoltaic cells for converting incident radiation energy into usable electric power will decline as the temperature of the photovoltaic cells rises as a result of the incident solar radiation. By conducting a heat-carrying medium, such as, for example, water, through the continuous cavity beneath the solar panel, heat accumulated in the solar panel can be led away via the medium in order to control a temperature of the photovoltaic cells. The heat conveyed with the medium can subsequently be used elsewhere.

In one embodiment thereof, the at least one of the one or more profiles is a heat pipe. Owing to its relatively high heat-transfer coefficient, a heat pipe is eminently suitable for conducting heat from the solar panel to a heat exchanger situated outside the panel holder, so that a temperature of the photovoltaic cells can be kept more or less optimal for efficiently converting solar radiation into electric power. Moreover, the extracted heat can be used for other purposes.

In one embodiment, the one or more profiles have a cross-sectional shape having a high bending resistance, in particular a T, I or U-shaped cross section. Such a cross section lends strength to the profiles precisely at those spots in the material which are most subjected to flexural load. The profiles, given a relatively long length, thus have an extremely good bending resistance, so that panel holders with lengths of 200 cm or longer can thereby be reliably supported, the bending resistance in the first direction being greater than the bending resistance in the second direction.

In one embodiment, the panel holders comprise a plastic, in particular a plastic chosen from the group PP, PE, PVC, PA, PET, fibre-reinforced variants, such as glass fibre variants thereof, a combination of two or more thereof, or a thermosetting synthetic resin such as fibre-reinforced polyester as a “sheet moulding compound” (SMC) or as a “bulk moulding compound” (BMC) or Resin Transfer Moulding (RTM) product. The use of plastic for the panel holder offers excellent load-bearing strength in relation to a total weight thereof and is, moreover, durable, weatherproof and maintenance-friendly. The solar panel can be relatively easily fastened thereto, for example by gluing. In addition, plastic makes any desired adaptation of the walls easily possible in order to integrate the various required functional properties in the device. In this context, it is important that a bending resistance of the plastic walls can be easily adapted according to requirement by a choice of material in combination with a wall thickness. A bending resistance of the walls can thus be adapted so as to deflect in a controlled manner in the second direction, i.e. about a bending axis in the first direction, when they are subjected to a maximally permitted load prescribed in the standards.

In one embodiment, the thickness of the glass plate is no greater than 3.2 mm, preferably no greater than 2.5 mm. The thinner the glass plate, the more bendable it is. The panel holder of the device makes it possible to use thin glass plates even for relatively large surfaces of more than 1 m², for example 2 m long and 1 m or 1.64 wide.

Preferably, the glass plate has a bending strength within the range 24 MPa-250 MPa, further preferably within the range 100 MPa-200 MPa. Such higher bending strength of the glass plate makes the glass plate more bendable in general.

In one embodiment, the glass plate is thermally or chemically tempered. Thermally tempered glass is glass that has undergone heat treatment in order to increase the bending resistance. Thermally tempered glass is sub-divided into thermally strengthened glass, also referred to as semi-tempered glass, and thermally toughened glass, also referred to as tempered glass. For the device according to the invention, thermally toughened glass is preferably used.

Thermally toughened glass has a relatively large impact resistance, for example 4 to 5 times greater than that of standard glass, and a relatively large bending strength, of, for example, 4 to 5 times greater than that of standard glass.

As a result of these mechanical properties of the thermally toughened glass, a thin glass plate of thermally toughened glass having a thickness within the range 0.5-4 mm is bendable. The bendability increases as the thickness of the glass plate decreases.

Chemically tempered glass is glass where the impact resistance and bending strength is considerably increased by means of a chemical treatment, for example treatment in a salt bath, wherein, via an ion exchange, a thin surface layer of high compressive stress is obtained, which layer strongly improves the mechanical properties of the glass. Chemically tempered glass can also be used in the device according to the invention. However, this glass is in general relatively expensive and hence less suitable from a cost-effectiveness perspective.

In one embodiment, the panel holder comprises coupling means for coupling to a further panel holder of a further device. A plurality of devices can thus be mutually coupled, wherein surfaces of consecutive solar panels form a more or less fully closed active surface, between which virtually no inactive parts are found.

The device according to the invention can be used as separate modules which are placed on a suitable foundation, for example a roof of a building. However, it is also possible to use the device according to the invention as an element integrated into a building or other construction. In such an application, the devices can fulfil a dual function, on the one hand as a structural element of a building, on the other hand as a generator of power from solar radiation. Examples of such integrated elements are, for example, facade panels or building integrated solar panels (BIPV “Building Integrated PV”), such as roof elements/roof tiles. The device can also be used to realize gently curved modules. Such curved modules can be used, for example, for roof coverings such as carports. The shape of such a module, which shape is preferably curved about a bending axis, can be preformed.

In one embodiment, the panel holder defines a surface which is curved about a bending axis and on which the solar panel can be fitted. The provision of a panel holder having a curved surface means that the solar panel is placed in a curved shape onto the surface. The solar panel hereby acquires a favourable pretensioning. In one embodiment, the panel holder parts are shaped such that they define the curved surface, whereby receiving cavities in the panel holder parts may be provided for receiving the one or more profiles conforming to the curved surface.

The invention further relates to a system for generating electric power from solar radiation, comprising a set of mutually coupled devices according to claims 1-33. The present invention further relates to a panel holder as used in the device according to claims 1-33.

The invention will now be explained in greater detail with reference to an illustrative embodiment and an accompanying drawing. In the drawing:

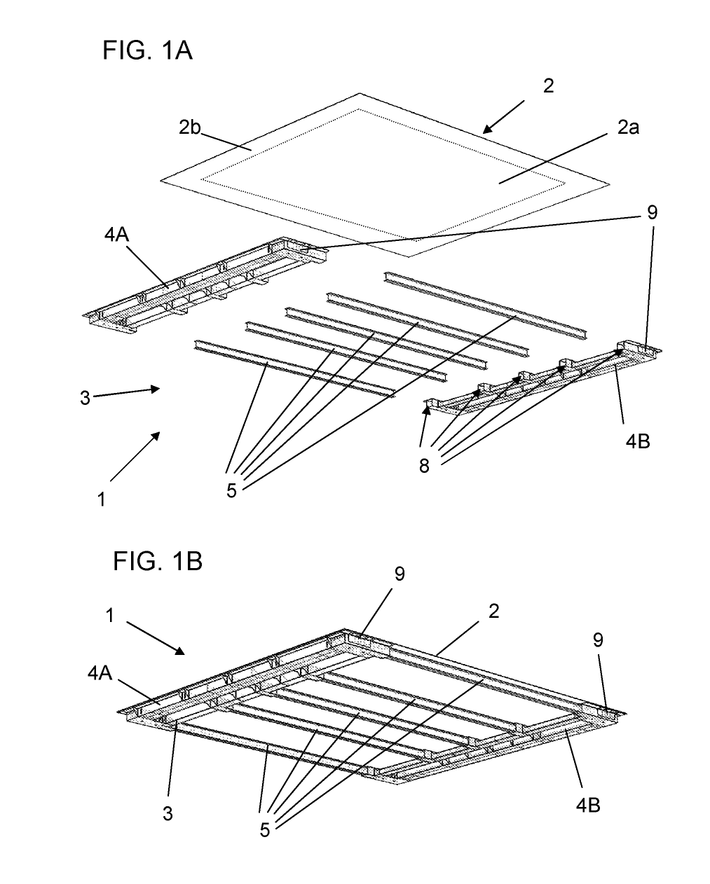

FIG. 1a shows a perspective disassembled view of an illustrative embodiment of a device according to the first and second aspect of the invention;

FIG. 1b shows a perspective assembled view of the illustrative embodiment of FIG. 1a;

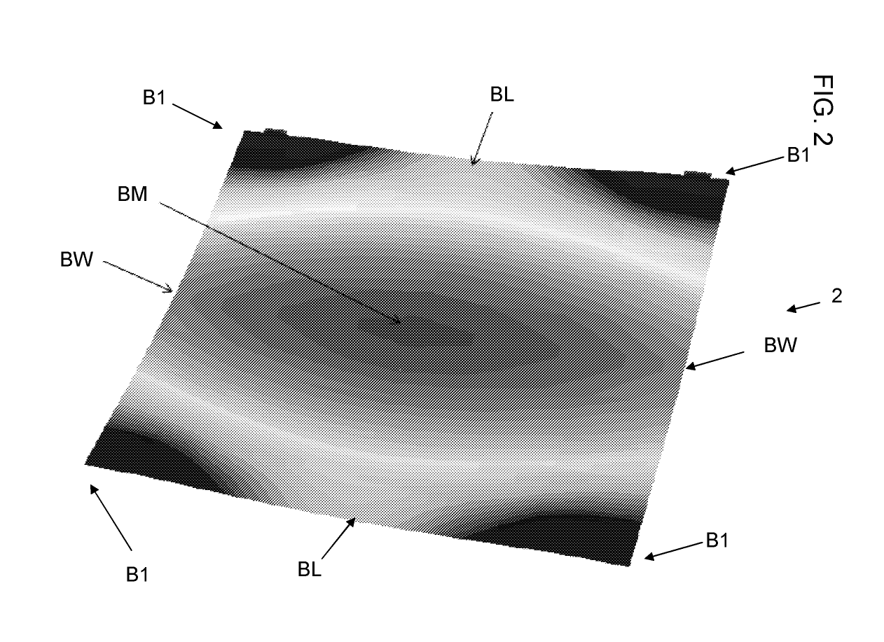

FIG. 2 shows a schematic representation of a bending profile of a device in the event of a load distributed evenly over the surface of the solar panel;

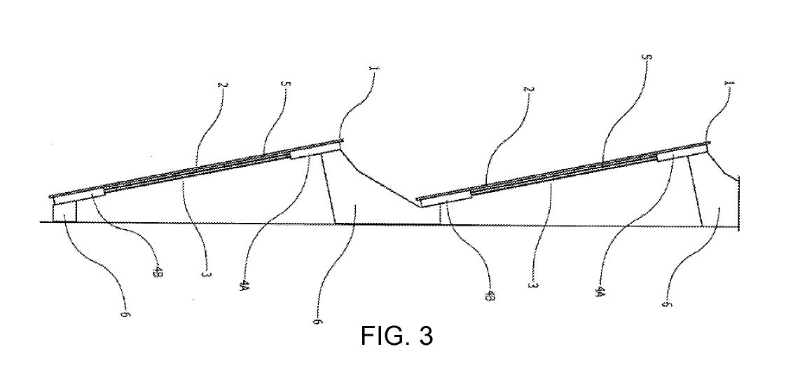

FIG. 3 shows a side view of a first illustrative embodiment of a system comprising a set of mutually coupled devices on a flat roof;

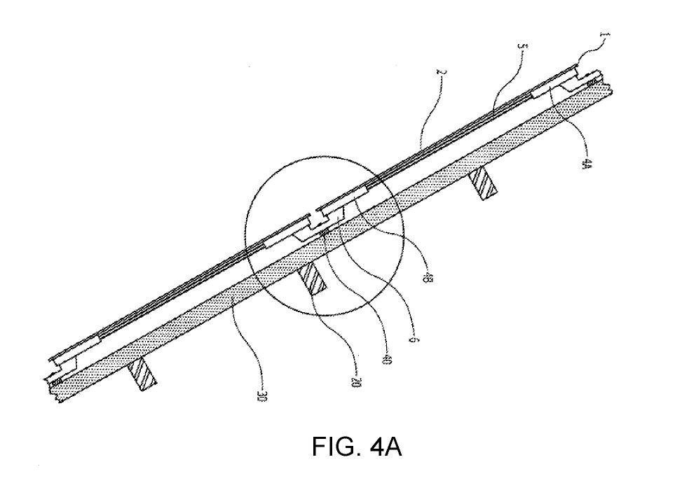

FIG. 4A shows a side view of a second illustrative embodiment of a system comprising a set of mutually coupled devices on a sloping roof;

FIG. 4B shows a detailed view of the second illustrative embodiment;

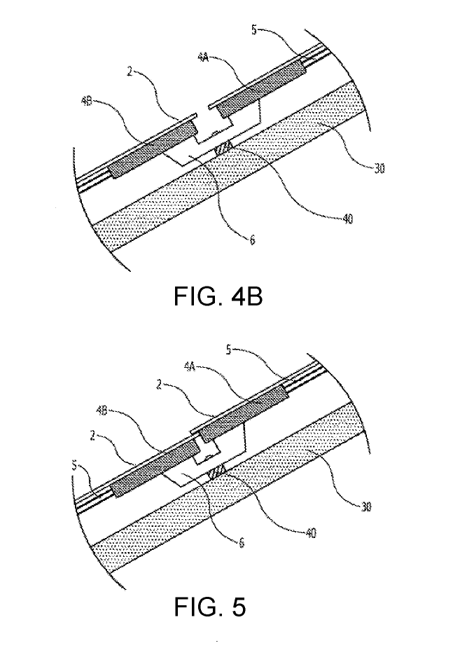

FIG. 5 shows a detailed view of a third illustrative embodiment of a system comprising a set of mutually coupled devices;

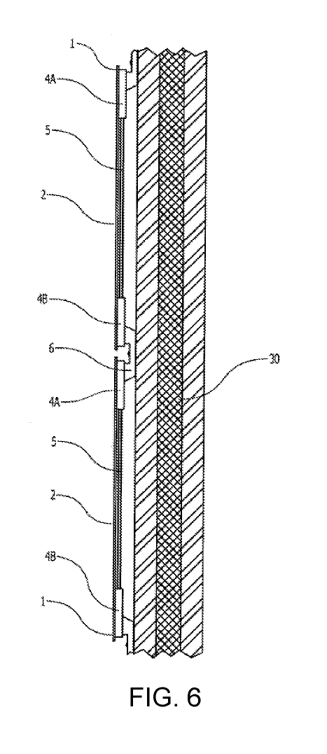

FIG. 6 shows a side view of a fourth illustrative embodiment of a system comprising a set of mutually coupled devices against a vertical wall;

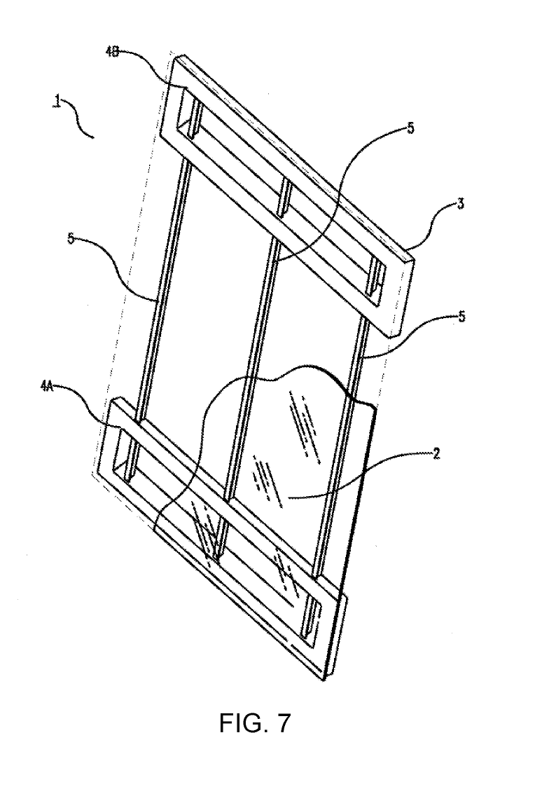

FIG. 7 shows a perspective view of a second alternative illustrative embodiment of a device according to the invention;

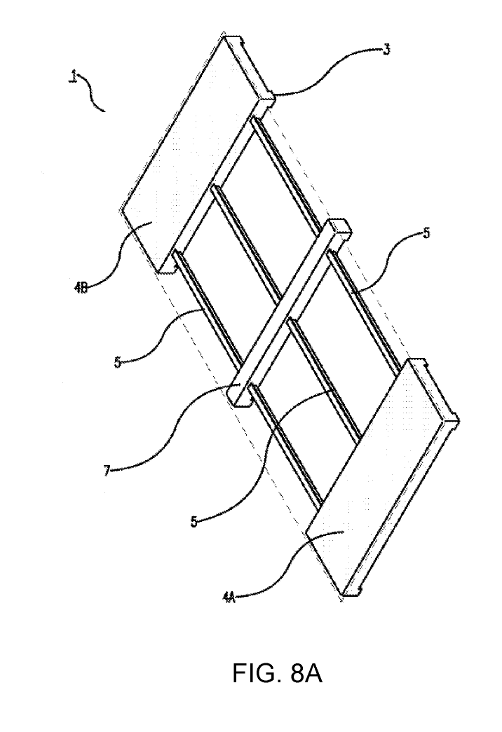

FIGS. 8A,B respectively show a perspective view and a top view of a third alternative illustrative embodiment of a device according to the invention;

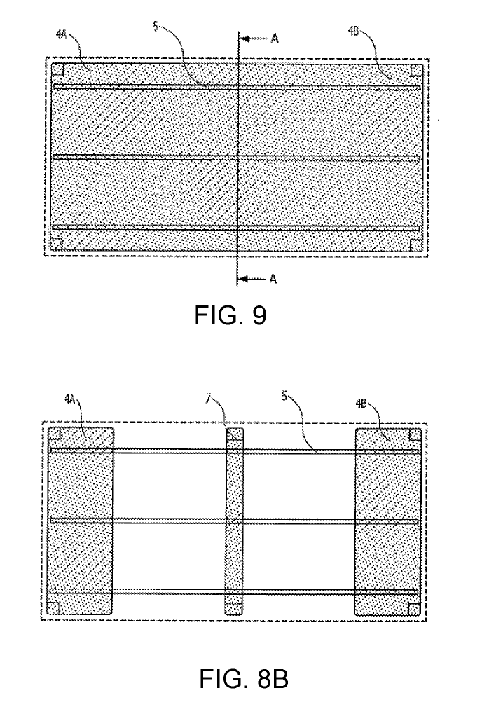

FIG. 9 shows a top view of a fourth alternative illustrative embodiment of a device according to the invention; and

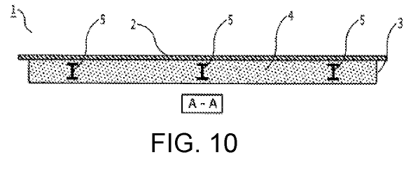

FIG. 10 shows a cross section along the line A of the illustrative embodiment of a device according to the invention from FIG. 9 with a first illustrative embodiment of a stiffening profile.

The figures are drawn, moreover, purely schematically and not to scale. In particular, for the sake of clarity, some dimensions can be represented exaggerated to a greater or lesser degree. Consistent parts are indicated in the figures, as far as possible, with the same reference numeral.

FIGS. 1a and 1b show an illustrative embodiment of a device according to the invention, denoted in its entirety by the reference numeral 1. The device 1 comprises a solar panel 2 of, for example, 2 by 1.64 metres, in which a layer of photovoltaic cells 2a is provided behind a glass plate 2b. The glass plate 2b protects the layer of photovoltaic cells 2a and is translucent such that it lets more or less all incident solar radiation through to the photovoltaic cells. The glass plate 2b and the layer of photovoltaic cells form a laminate, possibly with other plates or the like. The energy of the radiation directed onto the cells is converted by the photovoltaic cells into electric power which can be used as electricity for a variety of applications.

For a mechanical reinforcement of the solar panel 2, the device comprises a panel holder 3 to which the solar panel 2 is glued with a bonding agent suitable for the purpose. The bonding agent is, for example, a cement having a tensile strength characteristic of about 3 MPa and elongation properties of about 250% according to ISO 37.

The solar panel 2 is fastened by its underside onto the panel holder 3. The panel holder 3 does not on any side project beyond the solar panel 2. This is advantageous because the components of the panel holder 3 are unexposed or less exposed to potentially harmful influences such as precipitation and UV radiation. In other embodiments, it is quite possible for the panel holder to stick out from the solar panel, for example for coupling to an adjacent panel holder.

The circumferential edge of the solar panel 2 is totally free from a rigid frame which encloses the circumferential edge. The solar panel 2 is thus not provided with a rigid frame which encloses the circumferential edge of the solar panel and thus prevents the solar panel 2 from bending. It is possibly quite possible to cover the circumferential edge with a flexible element, for example a rubber band or strip, in order to prevent, for example, damage to or by the edge of the solar panel 2.

The panel holder 3 comprises a first panel holder part 4A which supports the solar panel 2 at a first end, and a second panel holder part 4B which supports the solar panel 2 at a second, opposite end. The first panel holder part 4A and the second panel holder part 4B maintain a mutual spacing, the panel holder parts 4A, 4B being coupled to each other by five parallel profiles 5. The profiles 5 here project with their ends into respective receiving cavities 8 in the material of the panel holder parts 4A,4B and are freely movable therein. As a result of such free coupling of the profiles 5 to the panel holder parts 4A,4B, the profiles have some freedom to move in the event of any deflection of the panel holder parts, so that torsional forces are not, or are scarcely, generated in the profiles.

The two panel holder parts 4A, 4B are shaped the same. Each of the profiles 5 is also shaped the same. Thus, for the production of a device 1, a solar panel 2 and a panel holder 3 are needed, wherein the panel holder 3 comprises two panel holder parts 4A, 4B and five profiles 5 of equal length. For the assembly of the device, the five profiles 5 are inserted with their ends into the receiving cavities 8, after which the solar panel is bonded onto the panel holder 3, the solar panel 2 preferably being bonded to both the panel holder parts 4A, 4B and the profiles 5.

By virtue of the fact that the profile 5 can be easily produced in a variety of lengths, a mutual spacing maintained by the panel holder parts 4A,4B is adjustable according to requirement by taking a number of profiles 5 of matching length. The panel holder 3 is hereby suitable for use with solar panels 2 of all sorts of varying dimensions. The panel holder parts 4A,4B themselves can here be produced with a uniform dimension. It may also be possible to provide different panel holder parts 4A, 4B of different dimensions in order to further increase variety in terms of dimensions. The number of profiles which couples together the panel holder parts 4A,4B can be tailored to the dimensions of the device 1.

In this illustrative embodiment, the profiles 5 comprise an elongate body of steel or aluminium. The profiles 5 make the panel holder 3 more rigid, particularly in the length direction, so that the panel holder 3 gives good support to the solar panel 2 received thereon. The profiles are of such strength that they offer the panel holder 3 in a length direction a bending resistance which is greater than a bending resistance of the panel holder parts 4A,4B in a width direction transversely to the length direction.

To this end, the panel holder parts 4A,4B are realized as relatively flat walls having sufficient strength and bearing capacity to reliably support the solar panel 2 up to at any rate the permitted loads prescribed in the standards. A wall thickness of the walls, together with a material thereof, is here tailored to allow bending of the panel holder parts 4A,4B in the width direction when a permitted load is exerted thereon. In this illustrative embodiment, the walls are made of a fibre-reinforced plastic, because the weight-strength ratio thereof lends itself particularly well to this application. Given a dimension of 1 metre in the width direction and 200 mm in the length direction, the walls made of such a plastic have the strength required for the device according to the invention if they are provided with a wall thickness of 3 mm. In this illustrative embodiment, a further weight reduction of the device 1 is achieved by the adoption of panel holder parts 4A,4B having an open central portion, because this provides savings in quantity of material and thus weight. The walls of the panel holder parts can have various wall thicknesses.

The panel holder parts 4A, 4B offer a base for possible integration of desired functions, such as, for example, a support base for the positioning of the device, a coupling base for a coupling of two or more devices, a base for fastening means for fastening to a foundation, integration of electrical connections and components, temperature control means, et cetera.

The fact that the panel holder parts 4A,4B have a bending resistance in the width direction which is lower than a bending resistance of the panel holder 3 in the length direction means that, a load which is distributed substantially evenly over the surface of the solar panel 2 will result in a first relative deflection of the panel holder 3, and the solar panel 2 held thereon, in the length direction which is substantially smaller than a second relative deflection of the panel holder 3, and the solar panel 2 held thereon, in the width direction. As a result, the bending of the solar panel is substantially about a single bending axis, which in this embodiment runs in the length direction.

The deflection of the device 1 will consequently be substantially smaller in the length direction than in the width direction. It is here advantageous that in the solar panel 2 the length direction is substantially the direction in which the photovoltaic cell or photovoltaic cells, or connections to or between the photovoltaic cell or cells, is most susceptible to deflection. The chance of damage to the layer comprising a photovoltaic cell or photovoltaic cells is hereby diminished.

FIG. 2 shows a representation of a three-dimensional bending profile of a device when a load is distributed evenly over the surface of the solar panel 2. The representation shows the deflection of the solar panel in the event of a substantially evenly distributed load upon the solar panel 2 of the device 1 of, for example, a test load of 2400 Pa.

The most deflection takes place in the middle BM of the solar panel 2. This is, for example, 65 mm. The least deflection takes place close to the corner points B1 of the glass plate 2b, because the panel holder 3 is supported close to these corner points B1 by means of the supporting bodies 9. The deflection at these corner points B1 is, for example, 0 mm. At the edges of the solar panel 2, the greatest deflection occurs close to the middle BW of the width edge. The deflection is here, for example, 50 mm, whilst the deflection in the middle BL of the length edges, which run in the length direction and are thus longer, is 25 mm.

As a result of the ratio of bending rigidities of the device 1 in the length direction and the width direction respectively, more deflection therefore occurs in the width direction than in the length direction, whereby the relative deflection, i.e. the amount of deflection per distance in the panel, in the width direction is thus also greater than the relative deflection in the length direction.

In the shown example, the relative deflection in the length direction is:

at the length edges (from B1 to B1 via BL) 25 mm/2000 mm=0.0125; and

in the middle (from BW to BW) (65−50=15 mm)/2000 mm=0.0075.

The relative deflection in the width direction is:

at the width edges (from B1 to B1 via BW) 50 mm/1640 mm=0.0305; and

in the middle (from BL to BL) (65−25=40 mm)/1640 mm=0.0244.

The relative deflection in the width direction is thus at least twice as great as the relative deflection in the length direction. This produces a deflection of the glass plate 2b which occurs substantially about one bending axis in the length direction, as can be seen from the deflection lines shown in FIG. 2.

Partly by virtue of the fact that this bending takes place substantially about one bending axis, damage to the photovoltaic cells and electrical cell connections can be avoided despite deflection of the glass plate 2b.

As a result of the relatively large deflection in the width direction, stresses are hereupon generated in the solar panel 2, which stresses ensure increased rigidity in the solar panel 2 in the length direction. The solar panel 2 can hereby withstand a higher load, or, specifically in order to withstand a prescribed maximally permitted load, or be made thinner, and thus lighter.

The device 1 comprises support bodies 9 with which the panel holder 3 can rest on a foundation without causing damage, and which, in the event of a maximally permitted load upon the solar panel 2, allow a deflection of the panel holder parts 4A,4B in the width direction. In this illustrative embodiment, the support bodies 9 comprise openings for the reception of support elements therein, which openings, close to each corner point of the panel holder 3, are provided in the panel holder parts 4A,4B. Each panel holder part 4A,4B here extends with a central part between two support bodies 9 and spans a space between the two support bodies 9. This space beneath the central part of the panel holder parts 4A,4B makes a deflection thereof in the width direction possible.

By virtue of the fact that, in the device 1 according to the invention, a bending in the solar panel 2 is allowed in the event of a load, for the solar panel of 2 m by 1 m it is possible to use a glass plate of 2 mm thickness which satisfies the strength required for such devices. The device is capable of withstanding a pressure exerted on the glass plate and suction force of 2400 Pa and/or 5400 Pa, and of thus satisfying the applicable standards IEC 61215:2005 and IEC 61646:2008.

The fact that the device according to the invention can adopt a relatively thin glass plate without needing a relatively heavy panel holder in return means that a total weight of the device can be considerably lower compared with devices in which thick glass panels and/or heavy panel holders are used.

The device hence offers a wide range of use, and a solar panel having relatively large dimensions of, for example, 160 cm by 100 cm (with, for example, 60×15.2 cm (6″) cells), or 200 cm by 100 cm (with, for example, 72×15.2 cm (6″) cells), or 200 cm by 164 cm (with, for example, 120×15.2 cm 6″ cells), can even be used on relatively weak roofs, such as, for example, light industrial roofs.

Although the profiles 5 in this illustrative embodiment are of solid construction, the profiles can instead optionally comprise in a length direction a continuous cavity which opens within the panel holder parts 4A,4B onto one end of the bodies. By connecting to the profiles 5 a line for a heat-carrying medium, such as, for example, water, the heat-carrying medium can be conducted through the cavity of the profiles. The heat-carrying medium, via a wall of the profiles, is in heat-exchanging contact with the solar panel. An accumulated heat can hence be led away from the solar panel via the medium in order to cool the solar panel, or, more specifically, heat can be supplied via a heated medium to the solar panel in order to actively melt away snow or ice on the solar panel, for example. A temperature of the photovoltaic cells in the solar panel can hereby be controlled according to requirement.

FIG. 3 shows an illustrative embodiment of a system comprising a set of mutually coupled devices 1. The devices 1 comprise a solar panel 2, which is fixed on a panel holder 3. In this illustrative embodiment, a suitable adhesive is used as the bonding agent, which adhesive connects the solar panel 2 and the panel holder 3 mutually one to the other. The panel holder 3 comprises on both sides beneath the solar panel 2 a plastic panel holder part 4A,4B, between which one or more elongate profiles 5, for example monolithic bodies 5 of glass-filament reinforced plastic, is fixed. The profile 5 can be produced, for example, by means of a pultrusion process, in which metal, or a plastic reinforced with glass filament, is drawn through a suitable die and hardened. A length of the profile 5 can in this case be easily made according to requirement. By thus adapting a length of each profile 5 according to requirement, a mutual spacing maintained by the panel holder parts 4A,4B is able to be adjusted, so that the panel holder 3 is suitable for use in solar panels of varying length.

The panel holder parts 4A,4B themselves can here be produced with a uniform dimension. The same shaped panel holder part can be placed on both sides. The device can hence offer a wide range of use, for relatively low production costs. The combination of the panel holder parts 4A,4B, with the solar panel 2 fixed thereon, and the profiles 5 placed between the panel holder parts thus results in a stable whole, wherein the panel holder parts remain in their place. A relatively thin glass plate having a thickness within the range 0.5 mm-4 mm can in this case be used. A use of thinner, and thus lighter, solar panels hereby becomes possible under the requirements laid down in standards IEC 61215 and IEC 61646.

Thus, in this illustrative embodiment, a solar panel 2 having a dimension of 100×200 cm and a thickness of about 3 mm is used. Besides the weight reduction which is offered by a thin solar panel of this type, the panel holder parts can also be produced as relatively compact and light plastic components. The thickness of the walls of the panel holder parts is, for example, within the range 1 mm-4 mm, preferably 1.5 mm-3 mm. The thickness of the device, i.e. the combination of panel holder 3 and the solar panel 2 held thereon, lies, for example, within the range 30 mm-60 mm.

The device can thus be realized in lightweight construction such that a use thereof on practically any type of foundation becomes possible, inclusive of relatively weak industrial or non-industrial roofs. The fact that the plastic panel holder parts 4A,4B form separate, relatively compact components of the device, makes a production process thereof, particularly in the case of larger dimensions of the panel holder, considerably simpler. In addition to a specific rigidity, strength, and stability, the panel holder parts further offer a base for possible integration of desired functions, such as, for example, a support base for the positioning of the device, a coupling base for a coupling of two or more devices, a base for fastening means for fastening to a foundation, integration of electrical connections and components, temperature control means, et cetera. By integrating a supporting structure in the device, it becomes possible to dispense with a separate supporting structure, thereby delivering an extra cost saving.

In this illustrative embodiment, the panel holder parts 4A,4B, with the support bodies thereof, are thus coupled to respective support elements 6, which are preferably made of the same plastic. The support elements 6 can be fastened by means of fastening means onto a foundation, such as a ground surface or a surface of an object. This can be realized in a customary manner, for example by means of a permanent fastening, but a fastening in which the surfaces does not need to be penetrated, such as by means of a superficial bonding with a bonding agent, is preferably adopted for this purpose. The support elements 6 comprise a first fastening part for fastening of a first of the devices 1 and at least a further fastening part for fastening of another of the devices 1. As shown in this illustrative embodiment, the fastening parts are situated apart in a vertical direction, so that, when a device 1 is placed on two consecutive support elements 6, an angle with respect to a horizontal is imposed on the solar panel 2. An angle can thus be imposed on the device 1 by a simple adjustment of or choice of support element 6, whereupon the solar panel 2 stands more or less optimally directed towards the sun in order to capture more solar radiation. Viewed from a solar radiation direction, two consecutive devices 1 of the system are in this case situated more or less side by side on the support element 6, so that the surfaces of the consecutive solar panels 2 form a more or less fully-closed active surface, between which virtually no inactive parts are found. An available surface of the foundation is thus utilized to optimum efficiency.

FIG. 4A and FIG. 4B show an alternative illustrative embodiment of a system in respectively a side view and a detailed view. The system comprises a set of mutually coupled devices 1, which are fastened to a foundation by means of a fastening means 40, which in this illustrative embodiment comprises a fastening member which is bonded to a surface of the foundation. The foundation can be any free surface, but in this illustrative embodiment, for illustration purposes, is a sloping roof comprising a layer of insulation material which is placed over a structural element of the roof 20, such as, for example, a roof beam. Consecutive devices 1 of the system are mutually coupled by means of a support element 6, which is bonded with the fastening member 40 to the foundation. The support element 6 comprises in this illustrative embodiment a first fastening part in order to support a first panel holder part 4A of a panel holder of a first device 1 from the set and a second fastening part in order to support a second panel holder part 4B of a panel holder of an adjacent device 1 from the set. A surface of both fastening parts on which the respective panel holder parts rest is parallel to the foundation, so that the adjacent devices are at the same height. The panel holders 3 can also be coupled to each other or to a supporting structure in any other suitable manner.

As is shown in FIG. 5 in a detailed view of a third illustrative embodiment of a system, a set of consecutive devices 1 is coupled together by a support element 6, which in this illustrative embodiment comprises a first fastening part, which places a first panel holder part 4A of a panel holder of a first device 1 from the set higher in relation to the foundation, than is the case with a second fastening part, which places a second panel holder part 4B of a panel holder of an adjacent device 1 from the set. The surfaces of consecutive solar panels 2 of the consecutive devices 1 hereby form a fully-closed active surface. Edges of the solar panels 2 even overlap to some extent to fully preclude inactive parts between the solar panels.

FIG. 6 shows a fourth illustrative embodiment of a system having a set of mutually coupled devices which are placed against a vertical wall 30 such as, for example, a facade. For this purpose, the devices 1 are fastened permanently to the facade with a fastening means suitable for this purpose.

FIG. 7 shows a second alternative illustrative embodiment of a device 1. The device 1 comprises a panel holder 3 having three parallel stiffening profiles 5 extending between two oppositely-situated panel holder parts 4A,4B of the panel holder 3. The stiffening profiles 5 are here fixed with the ends fully in the material of the panel holder parts 4A,4B. As a result of such an enclosure of the stiffening profiles 5 in the panel holder parts of the panel holder, any axial displacement thereof, whereby one of the ends of the body could inadvertently come loose from the panel holder parts, is precluded. The stiffening profiles 5 comprise in this illustrative embodiment an elongate monolithic body of steel or aluminium, having a high flexural rigidity. The stiffening profiles 5 hereby lend high rigidity to the panel holder 3, which rigidity thus gives good support to a solar panel 2 (partially illustrated) received thereon. A relatively thin solar panel 2 having a relatively large surface can hence reliably be used on the panel holder 3. The panel holder 3 thus boosts efficiency, both as regards a capture of a quantity of solar radiation, and as regards a weight reduction of the device. Thus, in this illustrative embodiment of a panel holder 3, a glass solar panel 2 having a thickness of just 2 millimetres can be used.

A still further weight reduction of the device 1 is realized in this illustrative embodiment by the adoption of panel holder parts 4A,4B having an open central portion, because this produces savings in terms of quantity of material, and thus weight.

An illustrative embodiment of a panel holder for use in a device 1 is shown in greater detail in FIG. 8A and FIG. 8B in a perspective view and top view respectively. The panel holder 3 comprises on both sides a panel holder part 4A,4B respectively, on which a solar panel (indicated with a dashed line) can be fixed, for example bonding by means of a bonding agent. Extending between the panel holder parts 4A,4B is a number of parallel elongate profiles 5. The profiles 5 comprise in a length direction a continuous cavity, which within the panel holder parts 4A,4B opens onto one end of the bodies, so that a line for a heat-carrying medium can be connected thereto. The heat-carrying medium, such as, for example, water, flows during use through the hollow profiles 5 in order to lead accumulated heat away from the solar panel via the medium in order to cool the solar panel, or, more specifically, to supply heat via a heated medium in order to actively melt away snow or ice on the solar panel, for example. A temperature of the photovoltaic cells in the solar panel can thus be controlled according to requirement. Any heat which is conveyed with the medium can be carried off or otherwise utilized. The profiles 5 in this illustrative embodiment are thus constructed as a heat pipe, which, owing to its relatively high heat-transfer coefficient, is eminently suitable for carrying heat from the solar panel to a heat exchanger situated outside the panel holder, so that a temperature of the photovoltaic cells can be kept more or less optimal for converting solar radiation efficiently into electric power. For an additional reinforcement of the heat pipes in a transverse direction, the panel holder 3 is provided with a further panel holder part 7, which, in a length direction of the panel holder 3, is placed more or less centrally beneath a solar panel received thereon, so that the further panel holder part 7 offers support precisely at the height of a weakest point in the solar panel, close to the centre. Through the combination of the panel holder parts 4A,4B and further panel holder part 7 with the bodies 5, the device 1 is particularly rigid and strong, whilst relatively little material is necessary for this, whereby an extremely lightweight device which can be widely used on a variety of foundations, inclusive of weak foundations which do not stand up well to heavier devices, is provided. It is noted that, if the ends of the panel holder part 7 are supported, for example by means of support elements, a large device 1 can be built, for example a solar panel having 240×15.2 cm (6″) cells with dimensions of 4 m by 1.64 m. Or a smaller, relatively elongate solar panel can in this way withstand a high compressive load.

A second illustrative embodiment of a panel holder for use in a device 1 is shown in greater detail in FIG. 9. The panel holder is here practically identical to the panel holder as shown in FIG. 8A and FIG. 8B, with the exception that the panel holder parts 4A,4B of the panel holder more or less fully surround the profiles 5, so that a fully-closed wall, which shields and thus protects an underside of the solar panel 2, is formed. Although in this illustrative embodiment somewhat more material for the panel holder parts 4A,4B is necessary than on the above-shown illustrative embodiment from FIG. 8A and FIG. 8B, the panel holder parts being smaller in terms of length dimension and thus leaving a clearance therebetween, the panel holder parts, through use of the profiles 5 therein, can be realized in thin construction, whilst retaining the required rigidity and strength, such that a total weight of the panel holder is always still sufficiently low for wide application of the device.

A first illustrative embodiment of a stiffening profile as used in a device is shown in greater detail in FIG. 10 in a cross section along the line A-A of a device as shown in FIG. 9. The device 1 comprises a solar panel 2, which is fixed on a panel holder 3 with a bonding agent, in this case a glue suitable for the purpose. The panel holder 3 comprises a plastics wall which fully surrounds a stiffening profile 5. The stiffening profile 5 comprises an elongate plastics or metal bar shaped body of I-shaped cross section. A bar shaped body of such cross section has a relatively high bending resistance, so that the panel holder 3, especially in the length direction of the stiffening profile, has a high rigidity which prevents deflection of the solar panel 2. By virtue of the fact that the wall of the panel holder itself can hereby be produced, for example, from separate parts, or can even, in part, be omitted, and the bar shaped body can be made much more simply from one piece, a sufficiently rigid panel holder can be obtained for relatively much lower cost in comparison with a plastic panel holder of the same size, the complete wall being produced from one piece.

Although the invention has been explained in detail with reference to just a few illustrative embodiments, it should be clear that the invention is by no means limited thereto. On the contrary, many more variations and manifestations are possible within the scope of the invention to an average person skilled in the art. For instance, the panel holder can serve both to support a solar panel having a single glass plate and, on a blind side, a layer of photovoltaic cells, and to support a solar panel based on thin film technology, in which a number of cells lies clamped between a first glass plate on a visible side and a second glass plate on a blind side. By virtue of the properties of the panel holder, relatively thin glass plates are possible for both types of solar panels, without loss of reliability and durability thereof.

1.-35. (canceled)

36. Device for generating electric power from solar radiation, comprising an elongated solar panel provided with at least one photovoltaic cell and a panel holder for holding the solar panel, characterized
in that the solar panel has a glass plate covering the photovoltaic cell and having a thickness within the range 0.5-4 mm, and
in that the panel holder comprises a panel holder part bonded to a side of the solar panel opposite the glass plate and extending in a second direction perpendicular to an elongation direction of the solar panel parallel to the glass plate and one or more elongated profiles extending in a first direction parallel to the elongation direction, wherein the panel holder part is configured and constructed to have a lower bending resistence than the one or more elongated profiles, such that a uniform load over the glass plate of the solar panel results in a largest first relative deflection of the device in the first direction which is smaller than a largest second relative deflection of the device in the second direction for allowing, when loaded, a stronger deflection of the device in the second direction perpendicular to the elongation direction for enhancing a strength in the first direction.

37. Device according to claim 36, wherein, in the event of a substantially uniform load over the surface of the solar panel, the largest relative deflection in the second direction is at least one and a half times the largest relative deflection in the first direction, or wherein, in the event of a substantially uniform load over the surface of the solar panel, the largest relative deflection in the second direction is at least twice the largest relative deflection in the first direction.

38. Device according to claim 36, wherein the uniform load over the glass plate of the solar panel results in a deflection of the device along lines in the plane of the solar panel, whereby the largest relative deflection along any of said lines in the first direction is smaller than the smallest relative deflection along any of said lines in the second direction.

39. Device according to claim 38, wherein the largest relative deflection along any of said lines in the first direction is at least 1.5 times smaller than the smallest relative deflection along any of said lines in the second direction.

40. Device according to claim 36, wherein the panel holder comprises four support bodies, which are fitted on or close to the corner points of the panel holder in order to support the panel holder and the solar panel held thereon.

41. Device according to claim 36, wherein the panel holder comprises at least one profile, which extends in the first direction beneath the solar panel, wherein the at least one profile on both sides is coupled to two panel holder parts and extends therebetween.

42. Device according to claim 36, wherein the solar panel is bonded onto the one or more profiles and/or onto the panel holder parts.

43. Device according to claim 36, wherein the one or more profiles are made of metal, in particular of steel or aluminium.

44. Device according to claim 36, wherein the one or more profiles projects with each of the ends thereof into a receiving cavity provided in the panel holder parts provided on both sides and is freely movable therein with the ends.

45. Device according to claim 36, wherein at least one of the one or more profiles comprises a cavity which runs through in the first direction and through which a heat-carrying medium can pass.

46. Device according to claim 36, wherein each of the one or more profiles lies with at least both ends fully enclosed in the panel holder parts.

47. Device according to claim 36, wherein the first panel holder part and the second panel holder part are made of plastic.

48. Device according to claim 36, wherein the panel holder comprises a plastic, in particular a plastic chosen from the group PP, PE, PVC, PA, PET, fibre-reinforced variants such as glass fibre variants thereof, a combination of two or more thereof, or a thermosetting synthetic resin, such as fibre-reinforced polyester, as a “sheet moulding compound” or as a “bulk moulding compound” or as a Resin Transfer Moulding (RTM) product.

49. Device according to claim 36, wherein the edge of the solar panel is free from a rigid frame which encloses the full circumferential edge of the solar panel.

50. Device according to claim 36, wherein the panel holder comprises coupling means for coupling to a further panel holder of a further device.
